(19) United States
(12) Patent Application Publication
(10) Pub. No.: US 2002/0144889 A1
(43) Pub. Date: Oct. 10, 2002

(54) Burn-in process for high density plasma PVD chamber

(75) Inventors: Rong Tao, San Jose, CA (US); Peijun Ding, San Jose, CA (US)

Correspondence Address: PATENT COUNSEL, APPLIED MATERIALS, INC., Legal Affairs Department, P.O. Box 450A, Santa Clara, CA, 95052, US

(73) Assignee: Applied Materials, Inc.

(21) Appl. No.: 09/829,547

(22) Filed: Apr. 9, 2001

(51) Int. Cl. C23C 14/34

(52) U.S. Cl. 204/192.12; 204/298.06; 204/298.08

(57) ABSTRACT

A burn-in process is performed in a high density plasma sputtering chamber to remove contaminants from a coil and a sputtering target installed in the chamber. The process includes applying respective power signals to the coil and to the sputtering target while maintaining a pressure level in the chamber that is lower than the conventional pressure level of 40 mT. Preferably the pressure level is maintained at substantially 10 mT.

### FIELD OF THE INVENTION

The present invention relates generally to semiconductor device manufacturing, and more particularly to a burn-in process employed in an high density plasma physical vapor deposition (HDPPVD) chamber.

### BACKGROUND OF THE INVENTION

FIG. 1 is a side diagrammatic illustration, in section, of the pertinent portions of a conventional high density plasma (HDP) sputtering or physical vapor deposition (PVD) chamber 100. The sputtering chamber 100 contains a coil 102 which is operatively coupled to a first RF power supply 104 via one or more feedthroughs 105. The coil 102 may comprise a plurality of coils, a single turn coil, a single turn material strip, or any other similar configuration. The coil 102 is positioned along the inner surface of the sputtering chamber 100, between a sputtering target 106 and a substrate pedestal 108. Both the coil 102 and the target 106 are formed from the to-be-deposited material (e.g., copper, aluminum, titanium, tantalum, etc.).

The substrate pedestal 108 is positioned in the lower portion of the sputtering chamber 100 and typically comprises a pedestal heater (not shown) for elevating the temperature of a semiconductor wafer or other substrate supported by the substrate pedestal 108 during processing within the sputtering chamber 100. The sputtering target 106 is mounted to a water cooled adapter 110 in the upper portion of the sputtering chamber 100 so as to face the substrate receiving surface of the substrate pedestal 108. A cooling system 112 is coupled to the adapter 110 and delivers cooling fluid (e.g., water) thereto.

The sputtering chamber 100 generally includes a vacuum chamber enclosure wall 114 having at least one gas inlet 116 coupled to a gas source 118 and having an exhaust outlet 120 coupled to an exhaust pump 122 (e.g., a cryopump or a cryoturbo pump). The gas source 118 typically comprises a plurality of processing gas sources 118a, 118b such as a source of argon, helium and/or nitrogen. Other processing gases may be employed if desired.

A removable shield 124 that circumferentially surrounds the coil 102, the target 106 and the substrate pedestal 108 is provided within the sputtering chamber 100. The shield 124 may be removed for cleaning during chamber maintenance, and the adapter 110 is coupled to the shield 124 (as shown). The shield 124 also supports the coil 102 via a plurality of cups 126a-b attached to, but electrically isolated from the shield 124, and via a plurality of pins 128a-b coupled to both the cups 126a-b and the coil 102. The coil 102 is supported by resting the coil 102 on the pins 128a-b which are coupled to the cups 126a-b. The cups 126a-b and the pins 128a-b comprise the same material as the coil 102 and the target 106 (e.g., copper) and are electrically insulated from the shield 124 via a plurality of insulating regions 129a-b (e.g., a plurality of ceramic regions). The sputtering chamber 100 also includes a plurality of bake-out lamps 130 located between the shield 124 and the chamber enclosure wall 114, for baking-out the sputtering chamber 100.

The sputtering target 106 and the substrate pedestal 108 are electrically isolated from the shield 124. The shield 124 may be grounded so that a negative voltage (with respect to grounded shield 124) may be applied to the sputtering target 106 via a first DC power supply 132 coupled between the target 106 and ground, or may be floated or biased via a second DC power supply 133 coupled to the shield 124. Additionally, a negative bias may be applied to the substrate pedestal 108 via a second RF power supply 134 coupled between the pedestal 108 and ground. A controller 136 is operatively coupled to the first RF power supply 104, the first DC power supply 132, the second DC power supply 133, the second RF power supply 134, the gas source 118 and the exhaust pump 122. The controller 136 includes computer program code adapted to control various operating parameters of the chamber 100 including the power levels provided by the power supplies 104, 132, 133, 134 and the pressure level in the chamber 100.

To perform deposition within the sputtering chamber 100, a substrate 138 (e.g., a semiconductor wafer, a flat panel display, etc.) is loaded into the sputtering chamber 100, is placed on the substrate pedestal 108 and is securely held thereto via a clamp ring 140. An inert gas such as argon then is flowed from the gas source 118 into the high density plasma sputtering chamber 100 and the first DC power supply 132 biases the sputtering target 106 negatively with respect to the substrate pedestal 108 and the shield 124. In response to the negative bias, argon gas atoms ionize and form a plasma within the high density plasma sputtering chamber 100. An RF bias preferably is applied to the coil 102 via the first RF power supply 104 to increase the density of ionized argon gas atoms within the plasma and to ionize target atoms sputtered from the target 106 (as described below).

Because argon ions have a positive charge, argon ions within the plasma are attracted to the negatively biased sputtering target 106 and strike the sputtering target 106 with sufficient energy to sputter target atoms from the target 106. The RF power applied to the coil 102 increases the ionization of the argon atoms, and, in combination with the coupling of the coil power to the region of argon and sputtered target atoms, results in ionization of at least a substantial portion of the sputtered target atoms. The ionized, sputtered target atoms travel to and deposit on the substrate 138 so as to form over time a continuous target material film 142 thereon. Because the sputtered target atoms are ionized by the coil 102, the target atoms strike the substrate 138 with increased directionality under the influence of the electric field applied between the target 106 and the substrate pedestal 108 (e.g., by the first DC power supply 132). The second RF power supply 134 may be employed to apply a negative bias to the substrate pedestal 108 relative to both the sputtering target 106 and to shield 124 to further attract sputtered target atoms to the substrate 138 during deposition.

In addition to target atoms, coil atoms are sputtered from the coil 102 during deposition and deposit on the substrate 138. Because of the coil's proximity to the wafer's edge the sputtered coil atoms predominantly coat the substrate 138 near its edges and, where the flat target atoms tend to deposit a center thick layer, result in overall uniformity of the thickness of the film 142 deposited on the substrate 138. Following deposition, the flow of gas to the high density plasma sputtering chamber 100 is halted, all biases (e.g., target, pedestal and coil) are terminated, and the substrate 138 is removed from the high density plasma sputtering chamber 100.

Occasionally the sputtering chamber 100 must be vented to the atmosphere to permit cleaning or routine maintenance and/or replacement of the sputtering target 106 and the coil 102. After the chamber 100 has been exposed to atmosphere, and before proceeding with deposition, decontamination processes must be performed to place the chamber in a suitable condition for deposition processing. One decontamination procedure is known as “bake-out”. During bake-out, the chamber 100 is maintained at an elevated temperature (e.g., via the bake-out lamps 130) for an extended period of time to de-sorb contaminants such as moisture or other gases from the chamber walls and other chamber components.

Another decontamination process is referred to as “burn-in” and is applied to the sputtering target 106 and to the coil 102. During burn-in the respective power signals are applied to the target 106 and to the coil 102, and contaminants such as surface oxides, or trace metals introduced into the target or coil during manufacturing, are removed by sputtering atoms or molecules from the target and coil. Typically, burn-in is carried out intermittently, with a sequence of substrates present in the chamber 100 for monitoring purposes. That is, a substrate is loaded onto the pedestal 108, a burn-in cycle is performed, and the substrate is removed and replaced with another substrate, whereupon another burn-in cycle is performed.

One application that has been proposed for HDP sputtering chambers is deposition of copper as a seed layer for electroplating. To obtain suitable Cu seed layer quality, it has been found to be desirable to provide active cooling of the substrate during the seed layer deposition. In order to provide active cooling, the conventional clamp ring (e.g., clamp ring 140) has been replaced with a low temperature biasable electrostatic chuck (LTBESC). However, the LTBESC has proven to be susceptible to malfunction or permanent failure resulting from contamination from copper evaporation from the coil that occurs during burn-in. To prevent chuck malfunction or permanent failure, the conventional burn-in process may be modified to reduce copper evaporation from the coil by reducing the duty cycle of the RF power signal applied to the coil. Also, to avoid substrate breakage, the dwell time in the chamber for each monitor substrate employed during burn-in may be reduced so that the total number of substrates used for monitoring was increased. However, these changes may result in a substantial increase in the total elapsed time required for burn-in, and a corresponding increase in the down-time for the sputtering chamber when maintenance is performed.

It would be desirable to provide a burn-in process that can be performed more rapidly, but without compromising the functioning of the LTBESC.

### SUMMARY OF THE INVENTION

An aspect of the invention provides a method of performing a burn-in process wherein contaminants are removed from a coil and a sputtering target installed in a high density plasma PVD chamber. The inventive method includes applying respective power signals to the coil and the sputtering target while maintaining a pressure level in the chamber of less than 40 mT. In one embodiment, the pressure level in the chamber is maintained at less than 25 mT, and in another embodiment at substantially 10 mT.

The present inventors have discovered that a burn-in process performed at a lower pressure is more efficient than a conventional burn-in process (e.g., typically performed at a pressure of at least 40 mT or higher), thereby permitting the total elapsed time for burn-in to be decreased and reducing overall down-time required for chamber maintenance.

Other objects, features and advantages of the invention will become more fully apparent from the following detailed description of the exemplary embodiments, the appended claims and the accompanying drawings.

### BRIEF DESCRIPTION OF THE DRAWINGS

FIG. 1 is a side diagrammatic illustration, in section, of components of a conventional high density plasma sputtering chamber;

FIG. 2 is a graph of coil voltage data obtained from coils that were burned-in using processes that varied in terms of chamber pressure, power level applied to target, and power level applied to coil;

FIG. 3 is a graph of copper resistivity data gathered from wafers processed according to conventional and inventive burn-in processes; and

FIG. 4 is a graph of data indicative of full-width-half-max (FWHM) readings for the Cu (111) peak obtained from monitor wafers processed in accordance with conventional and inventive burn-in processes.

### DETAILED DESCRIPTION OF PREFERRED EMBODIMENTS

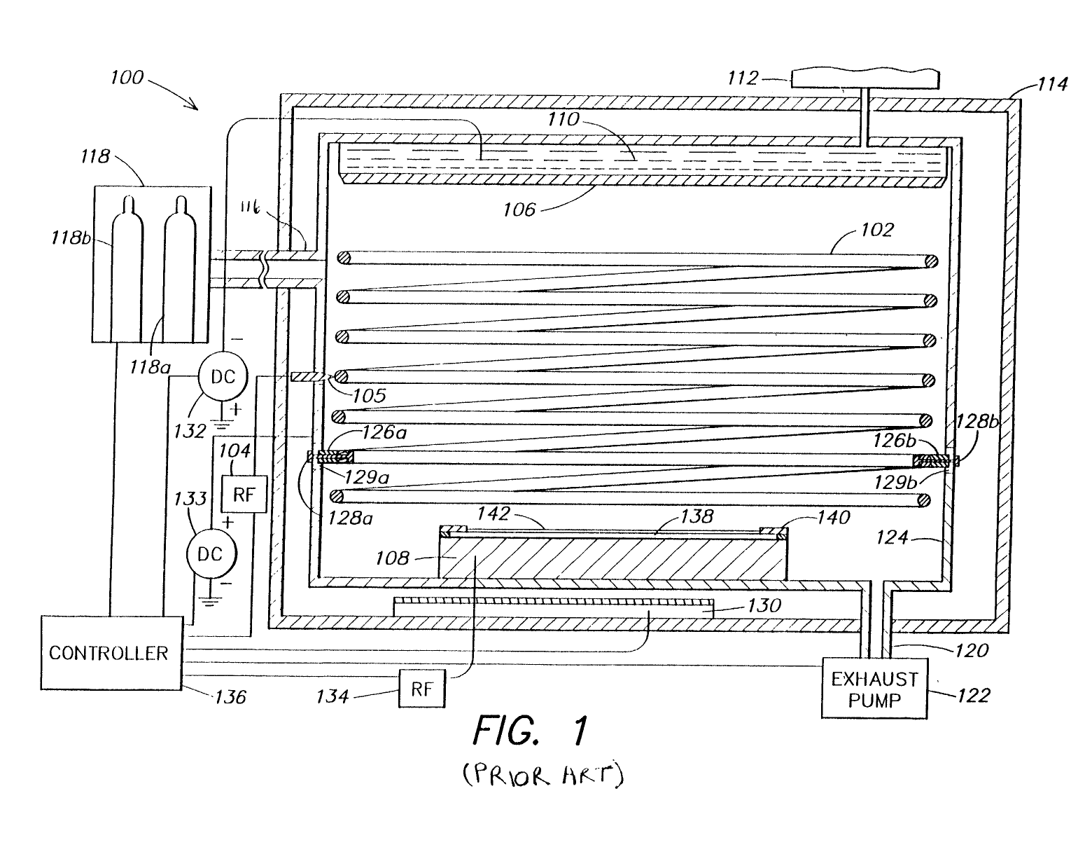

The present inventors carried out a series of experiments to determine the effects of process pressure, level of DC power applied to the target, and level of RF power applied to the coil on the efficiency of burn-in processes. These experiments were performed using an HDP sputtering chamber like that illustrated in FIG. 1, except that, as noted before, a LTBESC (not shown) was installed in place of the clamp ring 140. The coil voltage was taken as an indicator of the efficiency of the burn-in. In the experimental burn-in processes, the chamber pressure was varied in a range of 60 mT to 10 mT; the DC power supplied to the target was set at 1 kW, 1.5 kW and 2 kW; and the RF power applied to the coil was varied in a range of 2-5 kW.

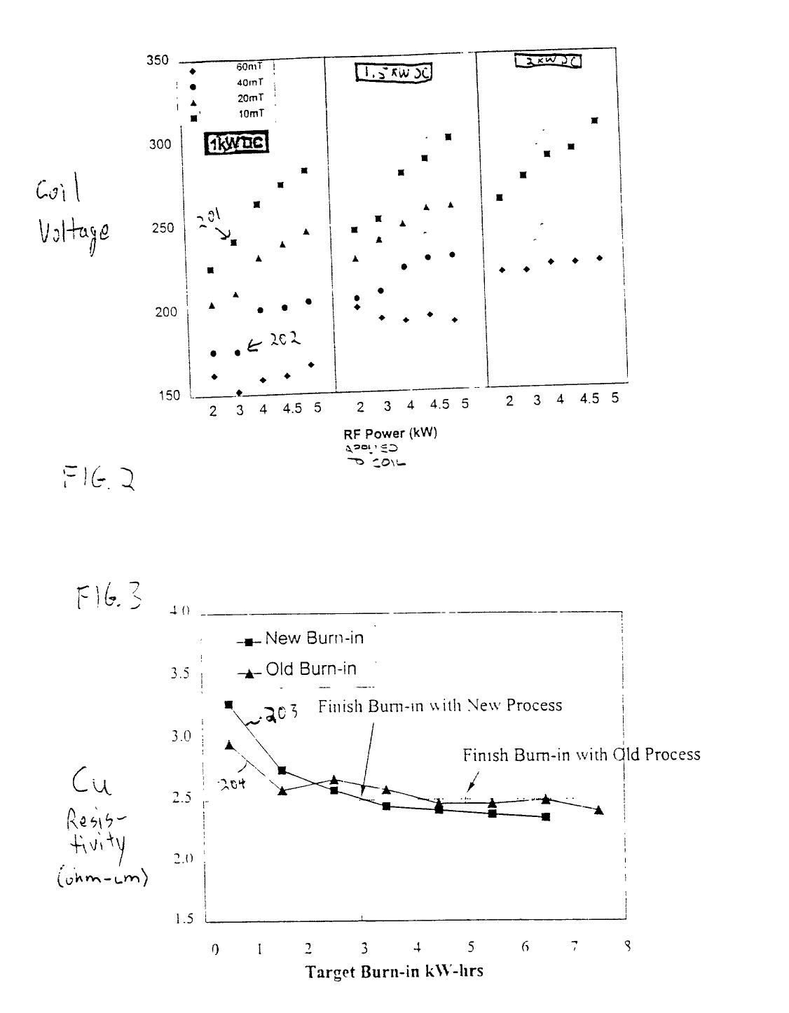

FIG. 2 presents data indicating the coil voltages obtained from the respective experimental burn-in processes. The left-hand third of the graph of FIG. 2 indicates results obtained from burn-in processes carried out with a DC power level applied to the target of 1 kW. The middle third indicates results obtained with a DC power level of 1.5 kW. The right-hand third of the graph indicates results obtained with the DC power level at 2 kW.

The results presented in FIG. 2 indicate that lowering the process pressure of the sputtering chamber, raising the DC power level applied to the target and raising the RF power level applied to the coil all generally have a positive effect on coil voltage. Of these three factors, lowering the process pressure is the most significant in increasing coil voltage (e.g., increase coil voltage and thus evidence improved burn-in efficiency). Moreover, there are constraints upon increasing the DC and RF power levels applied to the target and coil, respectively. As to increasing the RF power level applied to the coil, at increased levels the coil temperature is increased, leading to coil evaporation. As noted before, coil evaporation may interfere with the functioning of the LTBESC. On the other hand, increased DC power applied to the target may lead to net deposition from the target on the coil. Deposition from the target to the coil may generate particles, and may trap contaminants on the coil. However, lowering the pressure within the sputtering chamber does not suffer from these adverse effects, and therefore was considered to be the best way of improving the efficiency of the burn-in process.

With these factors in mind, the present inventors determined that an optimal recipe for the burn-in process called for 1 kW of DC power applied to the target, 3 kW of RF power applied to the coil, and a process pressure of 10 mT. This is in contrast to a conventional burn-in recipe of 1 kW-DC/3 kW-RF/40 mT. The duty cycle in both cases was 1:1 on:off. The improved efficiency of the lower-pressure recipe as compared to the conventional recipe is indicated by comparing data points 201 and 202 in FIG. 2. Data point 201 indicates that a coil voltage of 245 V was produced by the 1 kW-DC/3 kW-RF/10 mT recipe (the “new recipe”), whereas data point 202 indicates that a coil voltage of 170 V was produced by the 1 kW-DC/3 kW-RF/40 mT recipe (the “old recipe”). As stated previously, a higher coil voltage is indicative of a more effective burn-in process.

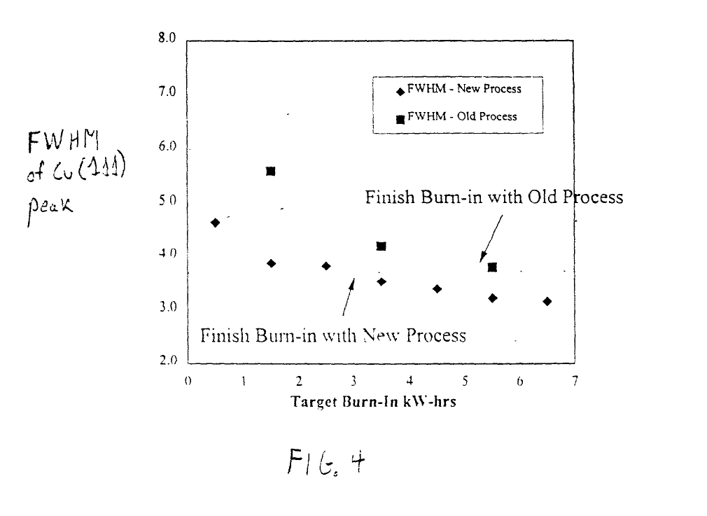

To confirm the improved effectiveness of the new recipe relative to the old recipe, further experiments were undertaken. In one set of experiments the resistivities of Cu films deposited on monitoring wafers were compared for burn-in processes using the old and new recipes. Results of this experiment are presented in FIG. 3. In FIG. 3, curve 203 plots resistivity data for Cu layers deposited during the new recipe burn-in process. Curve 204 plots resistivity data for Cu layers deposited during an old recipe burn-in process. In the case of both processes, resistivity decreases with increased burn-in duration, but after an initial period lower resistivity levels are achieved with the new recipe process. Taking a 2.5 ohm-cm deposited copper film as a benchmark indicative of a satisfactory burn-in, it will be noted that this level of resistivity is achieved with the new recipe burn-in process after applying a total of 3 kW-hr of DC power to the target. With a 1:1 on:off duty cycle, this amount of total applied power results in about a six-hour elapsed time for burn-in for a 1 kW level of DC power. On the other hand, with the old recipe process, the benchmark is not achieved until a total of 5 kW-hr has been applied to the target which requires about 10 hours.

In another confirming experiment, the texture of the Cu thin films deposited on monitor wafers was compared for the new recipe and old recipe processes. The full width half max (FWHM) of the Cu (111) peak was detected for each deposited copper film, and a benchmark of 3.8 or below was considered to indicate a satisfactory burn-in. FIG. 4 presents the results of this experiment. In FIG. 4 the diamond-shaped data points represent FWHM-Cu (111) peak figures for monitor wafers for the new recipe burn-in process. The square data points represent the results for monitor wafers for the old recipe burn-in process. Once more it will be observed that the desired benchmark was achieved with a burn-in corresponding to 3 kW-hr of DC power applied to the target with the new recipe, as compared to 5 kW-hr being required to achieve this benchmark using the old recipe process.

The monitor wafers were also examined using secondary ion mass spectroscopy (SIMS) and it was determined that a 3 kW-hr target burn-in using the new recipe performed satisfactorily in terms of eliminating trace metal contaminants.

Based on these results, it was determined that a burnin process using the new recipe could be satisfactorily terminated upon 3 kW-hr of DC power having been applied to the target. This is in contrast to the conventional process using the old recipe, in which a total of 5 kW-hr of DC power was applied to the target. The total elapsed time for the burn-in process using the new recipe was about 6 hours, as compared to 10 hours for the burn-in process using the old recipe. This represents a substantial reduction in time required for burn-in, and a corresponding reduction in the down-time required for maintenance of the HDP sputtering chamber.

The foregoing description discloses only exemplary embodiments of the invention; modifications of the above disclosed apparatus and method which fall within the scope of the invention will be readily apparent to those of ordinary skill in the art. For example, although the invention has been described in connection with burn-in of a copper target and copper coil, it is also applicable to burn-in of targets and coils for depositing other metals, such as Ti, W, and Ta. Moreover, the HDP chamber to which the invention is applicable need not be equipped exactly as described herein. Although the invention is particularly advantageous when used in a HDP sputtering chamber which uses an LTBESC, an LTBESC need not necessarily be employed.

Also, although it is preferred to perform the burn-in process at a chamber pressure of substantially 10 mT, it is within the scope of the invention to employ any pressure level that is less than the conventional level of 40 mT. Further, the inventive burn-in processes described herein may be performed within an HDP sputtering chamber during and/or after a bake out process is performed within the chamber (e.g., any conventional bake-out procedure used to bake out the walls, shield, target, pedestal or any other chamber surface). In accordance with at least one embodiment of the invention, an inventive HDP sputtering chamber may be provided based on the conventional HDP sputtering chamber 100 of FIG. 1 (or based on any other HDP sputtering chamber such as one that employs a LTBESC) by providing the controller 136 with computer program code adapted to perform a burn-in process by applying respective power signals to the coil and the target while maintaining the pressure level in the chamber at less than 40 mT.

Accordingly, while the present invention has been disclosed in connection with a preferred embodiment thereof, it should be understood that other embodiments may fall within the spirit and scope of the invention, as defined by the following claims.

The invention claimed is:

1. A method of performing a burn-in process wherein contaminants are removed from a coil and a sputtering target installed in a high density plasma PVD chamber, the method comprising applying respective power signals to the coil and the sputtering target while maintaining a pressure level in the chamber of less than 40 mT.

2. The method of claim 1, wherein the pressure level in the chamber is maintained at less than 25 mT.

3. The method of claim 2, wherein the pressure level in the chamber is maintained at substantially 10 mT.

4. The method of claim 3, wherein the power signal applied to the sputtering target is a DC signal at a level of substantially 1 kW and the power signal applied to the coil is an RF signal at a level of substantially 3 kW.

5. The method of claim 4, wherein the burn-in process is terminated upon substantially 3 kW-hr of power having been applied to the sputtering target.

6. The method of claim 1, wherein the sputtering target and the coil are formed of copper.

7. An apparatus comprising:
a high density plasma PVD chamber having:
a target;
a first signal source coupled to the target;
a coil;
a second signal source coupled to the coil;
a substrate pedestal; and
an exhaust system adapted to control a pressure level in the chamber; and
a controller coupled to the first signal source, the second signal source, and the exhaust system, the controller having computer program code adapted to perform a burn-in process by applying respective power signals to the coil and the target while maintaining the pressure level in the chamber at less than 40 mT.

8. The apparatus of claim 7, wherein the computer program code is adapted to maintain the pressure level in the chamber at less than 25 mT during the burn-in process.

9. The apparatus of claim 8, wherein the computer program code is adapted to maintain the pressure level in the chamber at substantially 10 mT during the burn-in process.

10. The apparatus of claim 9, wherein the computer program code is adapted to control the first and second signal sources such that a DC power signal is applied to the target at a level of substantially 1 kW and an RF power signal is applied to the coil at a level of substantially 3 kW.

11. The apparatus of claim 10, wherein the computer program code is adapted to terminate the burn-in process upon substantially 3 kW-hr of power having been applied to the target.

12. The apparatus of claim 7, wherein the target and the coil are formed of copper.

13. A method of decontaminating a high density plasma PVD chamber, comprising the steps of:
baking-out the chamber by applying heat to the chamber to desorb contaminants from a chamber surface; and
performing a burn-in process to remove contaminants from a coil and a sputtering target installed in the chamber by applying respective power signals to the coil and the sputtering target while maintaining a pressure level in the chamber of less than 40 mT.

14. The method of claim 13, wherein the pressure level during the burn-in process is maintained at less than 25 mT.

15. The method of claim 13, wherein the pressure level during the burn-in-process is maintained at substantially 10 mT.
